(19) United States
(12) Patent Application Publication
(10) Pub. No.: US 2007/0216420 A1
(43) Pub. Date: Sep. 20, 2007

(54) Method and system for eliminating VSWR errors in magnitude measurements

(75) Inventor: James Jaklitsch, Parkton, MD (US)

Correspondence Address: VENABLE LLP, P.O. BOX 34385, WASHINGTON, DC, 20043-9998, US

(73) Assignee: AAI Corporation, Hunt Valley, MD (US)

(21) Appl. No.: 11/369,986

(22) Filed: Mar. 8, 2006

(51) Int. Cl. G01R 27/28

(52) U.S. Cl. 324/612

(57) ABSTRACT

A method and system to eliminate the VSWR effect in measurements results are provided. Multiple measurements of the signal under test are taken to cancel out the VSWR effects and leave only the actual magnitude of the signal under test. Multiple measurements may be taken with the phase of the signal shifted. The phase of the signal under test should be shifted so as to cancel out the VSWR effects. For example, for each measurement taken of the signal under test, a corresponding measurement should be taken with the phase of the signal under test inverted.

### BACKGROUND OF THE INVENTION

1. Field of the Invention

The present invention relates generally to a system for measuring selected performance characteristics of electronic components. In one preferred embodiment, the present invention comprises a method and apparatus for evaluating selected performance criteria of microwave power components, and in particular, microwave transmitter and receiver components.

2. Related Art

In order to control equipment such as sensors, guns, and cameras, microwave components have long been critical features of radar systems, electronic devices, and other systems. Errors in the parameters of microwave components translate directly into decreased accuracy and precision of the equipment, systems, and processes in which they are employed. There has long been a need to improve the accuracy, reliability, and correlation of measurements of microwave power transmitter and receiver components. Improvement in the accuracy of the performance characteristics of microwave components contributes directly to improved accuracy and precision in the systems in which they are used.

A major source of error when measuring the signal power of microwave components is Voltage Standing Wave Ratio (VSWR). VSWR is a phenomena that occurs with all microwave systems. VSWR effects are produced whenever there is a mismatch in impedance in a microwave cable or transmission device. Whenever a microwave measurement is performed, the measurement includes a reflected wave resulting from the VSWR effects. The measurement is actually the sum of whatever is being measured plus the reflected wave. The VSWR effects produce errors in measurements of microwave systems and limit the ability to accurately measure the magnitude of the microwave signal.

Past attempts at limiting or removing the error caused by VSWR have focused on minimizing the impedance discontinuities that give rise to signal reflections and cause voltage standing waves to be produced. Once the impedance discontinuities are minimized to the fullest extent possible, the remaining VSWR effect is treated as an irreconcilable system error. In the known prior art, there is no effective means of removing the error caused by VSWR.

### BRIEF SUMMARY OF THE INVENTION

In an exemplary embodiment of the invention, a method for eliminating or reducing VSWR effects is provided. In embodiments of the invention, the method comprises receiving multiple measurements of a magnitude of a microwave signal with a phase of the signal shifted for each of the measurements; and determining a true magnitude of the microwave signal eliminating voltage standing wave effects based on the multiple measurements of the magnitude.

A system according to an exemplary embodiment of the invention comprises a measurement receiver adapted to receive a microwave signal under test and to take multiple measurements of a magnitude of the microwave signal under test; and an analyzer to receive the measured magnitudes and to determine a true magnitude of the signal under test canceling out voltage standing wave effects based on the measured magnitudes.

Further objectives and advantages, as well as the structure and function of preferred embodiments will become apparent from a consideration of the description, drawings, and examples.

### BRIEF DESCRIPTION OF THE DRAWINGS

The foregoing and other features and advantages of the invention will be apparent from the following, more particular description of a preferred embodiment of the invention, as illustrated in the accompanying drawings wherein like reference numbers generally indicate identical, functionally similar, and/or structurally similar elements.

FIG. 1 illustrates a system according to an exemplary embodiment of the present invention; and

FIG. 2 illustrates a flowchart of a method according to an exemplary embodiment of the present invention.

### DETAILED DESCRIPTION OF THE INVENTION

Embodiments of the invention are discussed in detail below. In describing embodiments, specific terminology is employed for the sake of clarity. However, the invention is not intended to be limited to the specific terminology so selected. While specific exemplary embodiments are discussed, it should be understood that this is done for illustration purposes only. A person skilled in the relevant art will recognize that other components and configurations can be used without parting from the spirit and scope of the invention.

Embodiments of the present invention may include apparatuses for performing the operations herein. An apparatus may be specially constructed for the desired purposes, or it may comprise a general purpose device selectively activated or reconfigured by a program stored in the device.

Embodiments of the invention may be implemented in one or a combination of hardware, firmware, and software. Embodiments of the invention may also be implemented as instructions stored on a machine-accessible medium, which may be read and executed by a computing platform to perform the operations described herein. A machine-accessible medium may include any mechanism for storing or transmitting information in a form readable by a machine (e.g., a computer). For example, a machine-accessible medium may include read only memory (ROM); random access memory (RAM); magnetic disk storage media; optical storage media; flash memory devices; electrical, optical, acoustical or other form of propagated signals (e.g., carrier waves, infrared signals, digital signals, etc.), and others.

Embodiments of the invention provide a method and system to eliminate the VSWR effect in measurements results. Multiple measurements of the signal under test are taken to cancel out the VSWR effects and leave only the actual magnitude of the signal under test. Multiple measurements may be taken with the phase of the signal shifted. The phase of the signal under test should be shifted so as to cancel out the VSWR effects. For example, for each measurement taken of the signal under test, a corresponding measurement should be taken with the phase of the signal under test inverted. The multiple measurements may be processed to cancel out completely VSWR effects.

In embodiments of the invention, a scalar measurement of the signal under test is made. The scalar measurement returns the magnitude of the signal. Four separate measurements of the signal magnitude may be made, with the phase of the signal shifted to each of the four quadrature phase states. The four measured magnitudes are processed to cancel out the VSWR effects and provide the true signal magnitude.

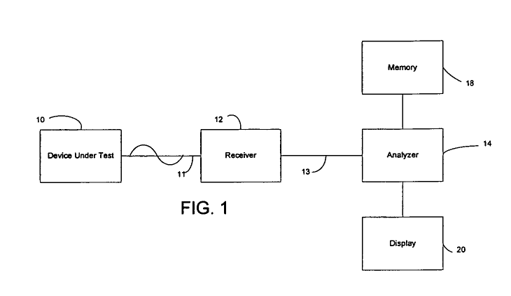

FIG. 1 illustrates an exemplary system according to an embodiment of the invention. A device under test (DUT) 10 provides a signal under test, for example via a microwave cable 11, to a measurement receiver 12. The DUT 10 may be any type of microwave component. In embodiments of the invention, the measurement receiver 12 may be capable of producing a scalar measurement of the signal under test. The measurement receiver 12 may be capable of measuring the RF signal magnitude of the signal under test. The measurement receiver 12 may be any type of signal receiver capable of such measurements, for example an RF power meter. The measurement receiver 12 provides an output, for example via a microwave cable 13, to analyzer 14. The analyzer 14 may perform the exemplary method described below to eliminate VSWR effects from the measured signal. Output may then be provided and displayed on display 20 in the desired fashion as is known in the art.

The measurement receiver 12 and analyzer 14 may be separate components or combined together, may be digital or analog-based systems, and/or may be embedded in hardware, coded, or written into application or operating system software in a PC-based or other hardware system. The measurement receiver 12 may measure other signal parameters from which the signal magnitude may be determined, for example, by the analyzer 14 or other components.

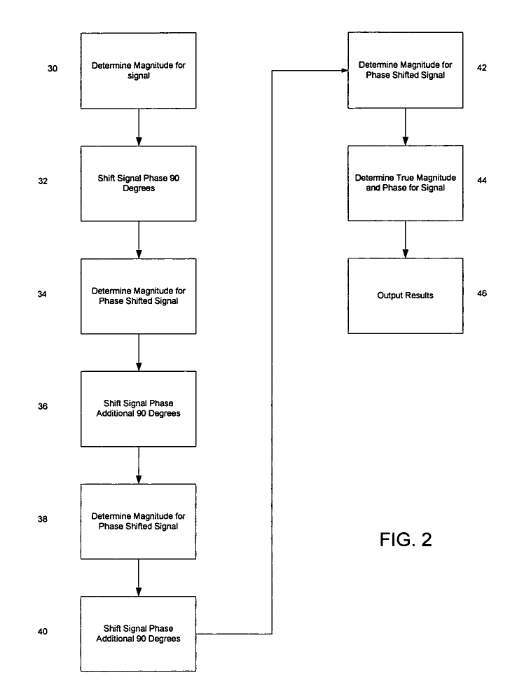

Turning now to FIG. 2, an exemplary method according to the present invention is described. The DUT 10 may be activated to generate the signal under test. The signal under test may be generated with an arbitrary phase and magnitude. The signal under test may be provided to the measurement receiver 12, for example, via cable 11 or other means. Measurement receiver 12 may make a first measurement to determine a magnitude Mₒ of the signal under test, step 30. The magnitude Mₒ may be provided via cable 13 to analyzer 14. The magnitude Mₒ may be stored, at least temporarily, in a memory 18. The memory 18 may be internal or external to the analyzer 14. The measurement receiver 12 may alternatively measure parameters of the signal from which the magnitude is determined, for example by the analyzer 14.

The phase of the signal under test may be shifted at its source. In this example, the phase of the signal under test is shifted by 90 degrees with respect to its original phase at the DUT 10, step 32. The magnitude of the signal under test should not be adjusted. Measurement received 12 may make a second measurement to determine a second magnitude M₉₀ of the phase shifted signal under test, step 34. The second magnitude M₉₀ may be provided to the analyzer 14 via cable 13. The second magnitude M₉₀ may be stored, at least temporarily, in the memory 18.

The phase of the signal under test may be shifted by 180 degrees with respect to its original phase at the DUT 10, step 36. The magnitude of the signal under test should not be adjusted. The measurement receiver 12 may make a third measurement of the phase shifted signal. Based on the third measurement, a third magnitude M₁₈₀ for the signal under test, is determined, step 38. The third magnitude M₁₈₀ may be provided to the analyzer 14, via cable 13. The third magnitude M₁₈₀ may be stored, at least temporarily, in the memory 18.

The phase of the signal under test may be shifted by 270 degrees with respect to its original magnitude at the DUT 10, step 40. The magnitude of the signal under test should not be adjusted. The measurement receiver 12 may make a fourth measurement of the phase shifted signal. Based on the fourth measurement, a fourth magnitude M₂₇₀ for signal under test is determined, step 42. The fourth magnitude M₂₇₀ may be provided to the analyzer 14. The fourth magnitude M₂₇₀ may be stored, at least temporarily, in the memory 18.

The analyzer 14 may process the measured magnitudes M₀, M₉₀, M₁₈₀, and M₂₇₀ to determine the true signal magnitude, step 44. The analyzer may obtain the measured magnitudes M₀, M₉₀, M₁₈₀, and M₂₇₀ from the memory 18. The true magnitude of the signal under test may be determined by averaging the measured magnitudes. This should cancel out the effect of VSWR and enables a true reading of signal magnitude to be obtained despite the continuing influence of VSWR. A true reading for the magnitude of the signal under test may be computed from the measured components M₀, M₀₀, M₁₈₀, and M₂₇₀ as follows:
Magnitude=(M₀+M₉₀+M₁₈₀+M₂₇₀)/4

The true magnitude may be shown, along with other desired information, on display 20, step 46.

In further embodiments of the invention, more than four measurements of the signal under test may be made and processed in accordance with the method outlined above. For example, eight measurements may be made with the phase of the signal shifted 0 degrees, 45 degrees, 90 degrees and 180 degrees, 225 degrees, 270 degrees, and 315 degrees. The measurements are averaged to eliminate the VSWR effects. The number of measurements may be extended to a sweep through all phases.

The embodiments illustrated and discussed in this specification are intended only to teach those skilled in the art the best way known to the inventors to make and use the invention. Nothing in this specification should be considered as limiting the scope of the present invention. All examples presented are representative and non-limiting. The above-described embodiments of the invention may be modified or varied, without departing from the invention, as appreciated by those skilled in the art in light of the above teachings. It is therefore to be understood that, within the scope of the claims and their equivalents, the invention may be practiced otherwise than as specifically described.

What is claimed is:

1. A method, comprising:
receiving multiple measurements of a magnitude of a microwave signal with a phase of the signal shifted for each of the measurements; and
determining a true magnitude of the microwave signal eliminating voltage standing wave effects based on the multiple measurements of the magnitude.

2. The method of claim 1, wherein determining the true magnitude comprises averaging the multiple measurements of the magnitude.

3. The method of claim 1, further comprising receiving four measurements of the magnitude.

4. The method of claim 1, wherein the phase of the microwave signal is respectively shifted to a quadrature state for the four measurements.

5. The method of claim 1, further comprising:
generating the microwave signal with a device under test; and
shifting the phase of the microwave signal at the device under test.

6. The method of claim 3, further comprising:
receiving the microwave signal at a measurement device; and
making the four measurements at the measurement device.

7. The method of claim 1, further comprising displaying the true signal magnitude on a display.

8. The method of claim 3, wherein the phase of the signal is shifted 0, 90, 180 and 270 degrees, respectively, for the four measurements.

9. The method of claim 3, further comprising storing the four measured magnitudes in a memory.

10. A system, comprising:
a measurement receiver adapted to receive a microwave signal under test and to take multiple measurements of a magnitude of the microwave signal under test; and
an analyzer to receive the measured magnitudes and to determine a true magnitude of the signal under test canceling out voltage standing wave effects based on the measured magnitudes.

11. The system of claim 10, further comprising a memory coupled to the analyzer and adapted to store the measured magnitudes.

12. The system of claim 10, further comprising a display coupled to the analyzer to display the true magnitude.

13. The system of claim 10, wherein the analyzer determines the true magnitude by averaging the measured magnitudes.

14. The system of claim 10, further comprising a device under test adapted to generate the microwave signal.

15. The system of claim 14, wherein the device under test is adapted to shift a phase of the signal under test to each quadrature phase.
